(19) United States
(12) Patent Application Publication
(10) Pub. No.: US 2025/0116970 A1
(43) Pub. Date: Apr. 10, 2025

(54) PORTABLE ELECTRONIC ITEM INCLUDING A SECURITY DEVICE FOR SECURING A COVER OF A REMOVABLE ELECTRICAL POWER SOURCE

(71) Applicant: ETA SA Manufacture Horlogère Suisse, Grenchen (CH)

(72) Inventor: David JOYE, Vauffelin (CH)

(73) Assignee: ETA SA Manufacture Horlogère Suisse, Grenchen (CH)

(21) Appl. No.: 18/887,431

(22) Filed: Sep. 17, 2024

(30) Foreign Application Priority Data
Oct. 6, 2023 (EP) 23202218.6

(51) Int. Cl. G04G 17/08; G04C 10/00; H05K 5/00; H05K 5/02

(52) U.S. Cl. CPC G04G 17/08; G04C 10/00; H05K 5/0086; H05K 5/0208

(57) ABSTRACT

A portable electronic item (100) including: a casing (10) having a compartment (11) that houses an electrical power source (2); a compartment cover (20) including first coupling means (23a) that cooperates with second coupling means (23b) provided on the casing (10) to rigidly connect the cover (20) to the casing (10) by rotating the cover about a rotational axis formed by a central axis (X) of the cover (20). The cover (20) has an indentation (22) provided in an outer face (21) to receive a tool for rotating the cover (20). A security device (30, 30′) is rigidly connected by clipping onto the portable electronic item and is configured to at least partially cover the indentation (22) of the cover (20) of the compartment (11), so as to prevent the introduction of a tool for rotating the cover (20) and removing it from the casing (10).

### CROSS REFERENCE TO RELATED APPLICATIONS

This application is claims priority to European Patent Application No. 23202218.6, filed on Oct. 6, 2023, the disclosures of which are incorporated by reference herein their entireties.

### TECHNICAL FIELD OF THE INVENTION

The invention relates to portable electronic items powered by a removable electrical power source, such as a battery, accumulator or cell, housed in a compartment of a casing and closed by a cover.

The invention relates more particularly to a security device configured to secure a cover of a removable electrical power source and to prevent its removal, so as to prevent access to the electrical power source while the security device is in place.

The invention is of particular interest in the field of watchmaking and relates more particularly to an electronic or electromechanical watch.

### TECHNOLOGICAL BACKGROUND

Portable electronic items can be powered by one or more removable power sources, such as batteries, accumulators or cells.

For example, electronic or electromechanical watches are powered, at least in part in the case of electromechanical watches, by a removable electrical power source, for example a button cell, which is housed in a compartment in the watch case. A removable cover is provided to enclose the battery inside the compartment, while ensuring that the compartment is at least watertight.

To allow the battery to be easily replaced, the cover and the case typically have fast, rotational coupling/uncoupling means which allow quick access to the battery, as well as fast closure of the compartment after the battery has been replaced. These fast coupling/uncoupling means are, for example, quarter-turn type assembly systems or bayonet type assembly systems.

Moreover, the cover can have an indentation in its outer surface configured to receive the end of a tool to provide for the rotation thereof. To further facilitate battery replacement, it is common for this indentation to have a relatively simple and common shape, such as a slot, so that various accessories available to the wearer can be used to open the compartment without the need for a specific tool, or the need to take the watch to a watchmaker for battery replacement.

However, these various interesting and advantageous technical solutions for replacing the battery can also present drawbacks in certain situations, particularly when handled by children, especially young children. This is because young children could inadvertently remove the battery cover and gain access to the battery compartment, which could lead to the battery being swallowed and all of the serious consequences that could entail.

As a result, there is a need to secure this type of portable item to prevent an irresponsible person, particularly young children, from accessing the battery compartment, while retaining the advantages of the easy and quick removal of the cover without the need for a specific tool.

### SUMMARY OF THE INVENTION

To this end, the invention aims to propose a security device for securing a cover to a compartment for a removable electrical power source, such as a cell, accumulator or battery, of a portable electronic item, which device can be used to overcome at least one of the aforementioned drawbacks.

In this context, the invention relates to a portable electronic item including:
a casing having a compartment configured to receive and house at least one removable electrical power source;
a compartment cover including first coupling means configured to cooperate with second coupling means provided on the casing so as to rigidly connect the cover to the casing by rotating said cover about a rotational axis formed by a central axis of the cover; said cover having an indentation provided in an outer face, said indentation being configured to receive a tool for rotating the cover.

Moreover, the portable electronic item includes a security device rigidly connected by clipping onto said portable electronic item, said security device being configured to at least partially cover the indentation of the compartment cover, so as to prevent the introduction of a tool for rotating the cover and removing it from the casing.

Thus, the clipped security device renders the indentation unusable as long as the security device is in place, by superimposing itself on top of the indentation so as to fill it and/or conceal it.

Moreover, the clipping connection method makes it easier to fit the security device by simply applying pressure in the direction of the cover. This attachment method also makes it possible to reverse the mounting of the security device on the portable electronic item and to make it easier for an authorised or responsible person to remove the cover if necessary.

Preferably, the security device is rigidly connected to the cover by clipping.

In addition to the features mentioned in the preceding paragraph, the portable electronic item according to the invention can have one or more complementary features from among the following, considered either on an individual basis or according to any combination technically possible:
the security device includes a main body having a flat surface, and attachment clips extending from the flat surface of the main body, the attachment clips cooperating with hooking apertures formed in the cover and configured to ensure that the security device is held by clipping onto the cover;
the security device is rigidly connected to the casing by clipping;
the security device includes a main body having a flat surface, and attachment clips extending from the flat surface of the main body, the attachment clips cooperating with hooking apertures formed in the casing and configured to ensure that the security device is held by clipping onto the casing above the cover;
the attachment clips project from the flat surface of the main body and extend towards the compartment;
the casing includes notches formed in the periphery of the cover and the attachment clips are housed in the notches so as to prevent the cover from being rotated relative to the casing when the security device is rigidly connected, by clipping, to the portable electronic item;
the main body has a cut-out allowing a small tool to pass into the indentation to facilitate the unclipping of the security device clipped onto the portable electronic item;
the security device is made of a metal or polymer material;
the portable electronic item is a timepiece.

### BRIEF DESCRIPTION OF THE FIGURES

The purposes, advantages and features of the present invention will be better understood upon reading the detailed description given below with reference to the following figures:

FIG. 1 is a view illustrating the back or rear of a portable electronic item according to the invention including a first example embodiment of a security device for securing a cover of a removable electrical power source, such as a cell, accumulator or battery;

FIG. 2 is a semi-exploded, perspective view of the portable electronic item illustrated in FIG. 1;

FIG. 3 shows how the security device is fitted to the portable electronic item shown in FIG. 1, when the compartment is closed by the cover;

FIG. 4 is a partial cross-sectional view of the portable electronic item shown in FIG. 1 showing more particularly the first example embodiment of the security device clipped onto the cover;

FIG. 5 is a partial cross-sectional view of a second example embodiment of a portable electronic item, showing more particularly a second example embodiment of a security device clipped onto the casing.

In all the figures, common elements bear the same reference numerals unless specified to the contrary.

### DETAILED DESCRIPTION OF THE INVENTION

Typically speaking in the present application, the outer face is understood to mean a face directed towards the exterior of the portable electronic item and, conversely, the inner face is understood to mean a face directed towards the interior of the portable electronic item.

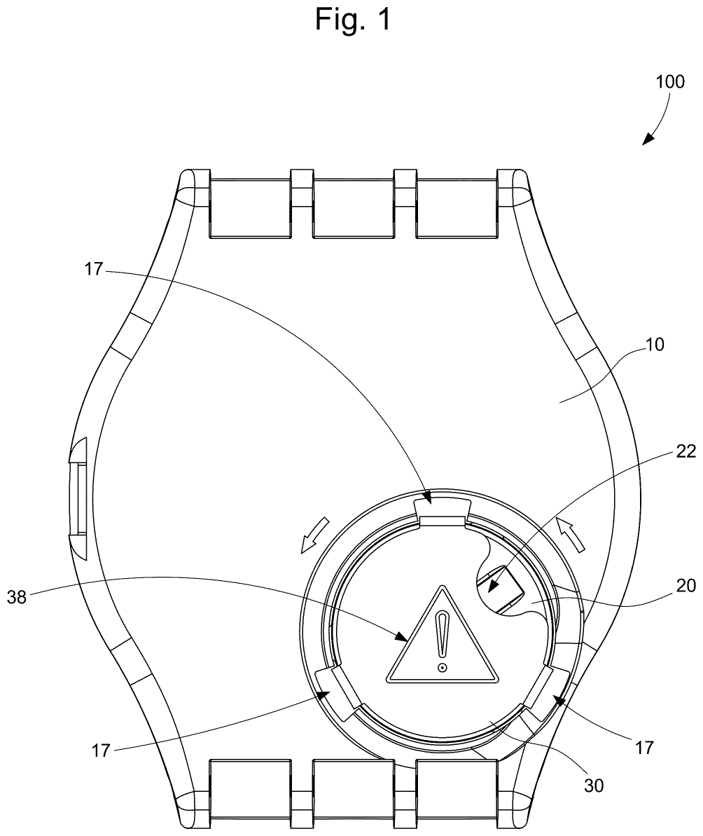

FIG. 1 is a view illustrating the back or rear of a casing of a portable electronic item 100 according to the invention including a first example embodiment of a security device for securing a cover of a removable electrical power source, such as a cell, accumulator or battery.

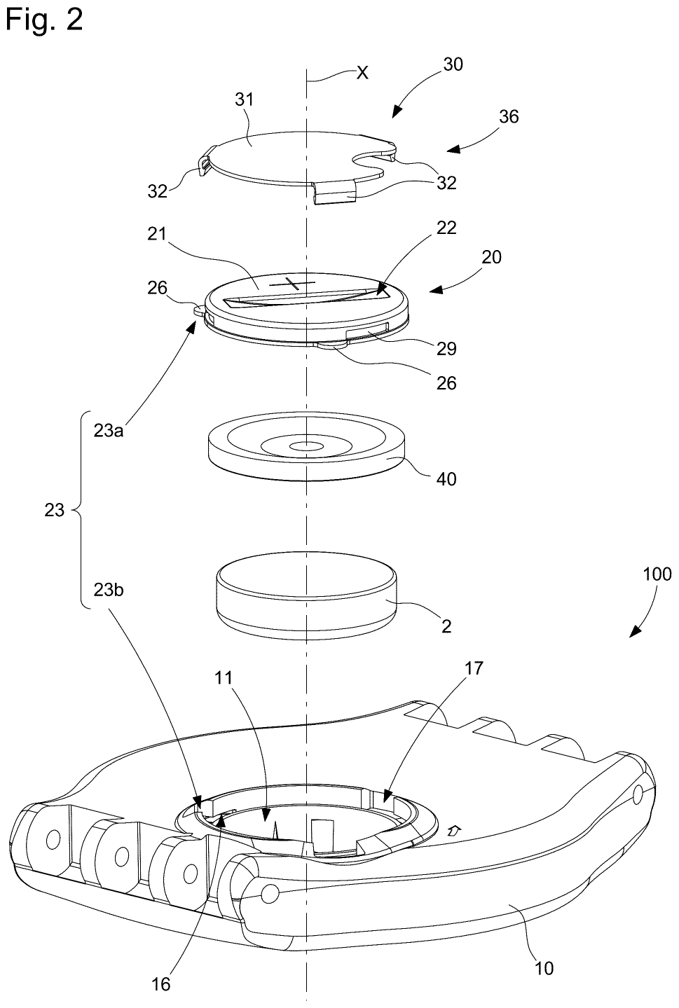

FIG. 2 is a semi-exploded, perspective view of the portable electronic item 100 shown in FIG. 1.

The portable electronic item 100 is, for example, a timepiece, such as a watch. However, other example embodiments are possible.

With reference to FIGS. 1 and 2, the portable electronic item 100 includes a casing 10 (or a watch case when the item is a watch) enclosing an electronic unit (not shown) powered by at least one removable electrical power source, for example in the form of a cell, an accumulator, a rechargeable battery or a battery.

As can be seen in FIG. 2, the casing 10 has a compartment 11 configured to receive and house at least one removable electrical power source 2, for example a cell or a battery.

Typically, on a watch, the compartment 11 is located at the rear or back of the watch, i.e. at a part of the watch intended to come into contact with the user's skin.

Depending on the electrical power required by the portable electronic item, the compartment 11 can be sized to receive and house a plurality of removable electrical power sources, for example a plurality of cells, accumulators or batteries.

In the remainder of this application, the removable electrical power source 2 will be considered to be a cell battery.

The cell battery 2 housed in the compartment 11 is a button cell for example.

The compartment 11 of the casing 10 forms a recess that is, for example, cylindrical in shape, extending substantially along a central axis X.

The compartment 11 of the casing 10 is closed by a cover 20 with a central axis X. The compartment 11 is closed by rotating the cover 20 about the central axis X.

The cover 20 includes first coupling means 23a configured to cooperate with second coupling means 23b provided on the casing 10. The coupling means 23a, 23b are configured to rigidly connect the cover 20 to the casing 10 by rotating said cover about the central axis X. The first coupling means 23a and the second coupling means 23b thus form a system 23 for attaching the cover 20 to the casing 10.

Preferably, the coupling means 23a, 23b of the attachment system 23 are fast, rotational coupling means, allowing the compartment 11 to be opened quickly and easily.

Preferably, the coupling means 23a, 23b are, for example, means allowing quarter-turn coupling or bayonet coupling.

For example, the cover 20 has tabs 26 extending radially relative to the central axis X. The tabs 26 are configured to cooperate and fit into grooves 16 formed in the casing 10 around the periphery of the compartment 11. Thus, the tabs 26 of the cover 20 form the first coupling means 23a and the grooves 16 in the casing 10 form the second coupling means 23b.

According to one alternative embodiment, the coupling means 23a, 23b are screw coupling means, so that the cover 20 is rigidly connected to the casing 10 by screwing.

The cover 20 has an indentation 22 made in an outer face 21, i.e. the face of the cover 20 visible to the user when the cover 20 is coupled to the casing 10.

The indentation 22 is formed by a surface set back from the outer face 21. The indentation 22 is shaped to receive the end of a dismantling tool and ensure rotation of the cover 20 when a rotation torque is exerted on the cover 20 using the dismantling tool.

Preferably, the indentation 22 has a simple shape. For example, the indentation 22 has the shape of a groove, a straight notch or a slot.

The indentation 22 can also have other, more complex shapes.

The casing 10 further includes notches 17 distributed around the periphery of the compartment 11 and extending substantially along the axis X and into which the grooves 16 open out. The casing 10 includes as many notches 17 as there are tabs 26 on the cover 20.

The notches 17 are configured to receive the tabs 26 of the cover 20 for coupling of the cover 20, by the rotation thereof, thus engaging the tabs 26 in the grooves 16. When the tabs 26 are at the bottom of the grooves 16, the cover 20 is coupled to the casing 10 and the compartment 11 is closed.

The grooves 16 can be raised or embossed to indicate the passage of a certain angular position and provide a sensory indication that the cover 20 has been closed correctly.

As shown in FIG. 2, a resilient membrane 40 is inserted between the cell battery 2 and the cover 20 to seal the compartment 11.

The portable electronic item 100 further includes a security device 30 assembled to the portable electronic item 100 by clipping.

Clipping is understood to refer to a reversible assembly of two elements by means of clamps or clips.

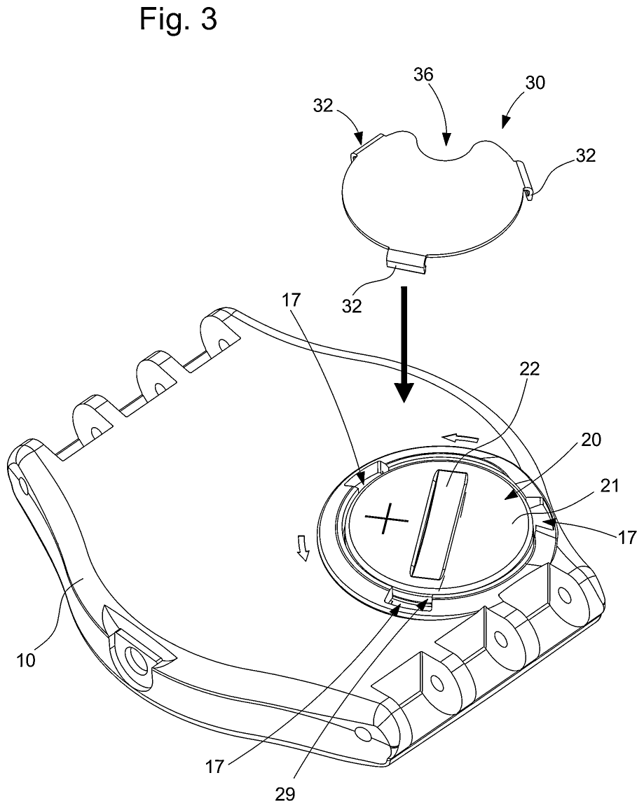

The security device 30 is an attachment which is rigidly connected onto the portable electronic item 100 by clipping by means of attachment clips which engage in raised portions provided for this purpose. The security device is rigidly connected to the portable electronic item 100 once the cover 20 is coupled to the casing 10, and closes the compartment 11, as shown in FIG. 3. FIG. 3 shows the cover 20 in the closed position on the casing 10 and the tabs 26 of the cover 20 are inserted in the grooves 16.

The security device 30 includes a main body 31 forming a flat surface and elastically deformable attachment clips 32.

The attachment clips 32 project from the flat surface of the main body 31.

For example, the attachment clips 32 are resilient lugs extending in a raised manner relative to the flat surface of the main body 31 and which have a hook at their free end.

The attachment clips 32 extend in a direction at an angle of between approximately 45° and 120° relative to the plane formed by the flat surface of the main body 31, and are directed towards the casing 10.

The attachment clips 32 are configured to cooperate with hooking apertures so as to rigidly connect the security device 30 to the portable electronic item 100 by clipping.

In this first example embodiment illustrated in FIGS. 1 to 4, the security device 30 is rigidly connected to the cover 20 by clipping.

To this end, the cover 20 has hooking apertures 29 formed in the outer side of the cover 20 and configured to cooperate with the end of the attachment clips 32, to hold the security device 30 in position on the cover 20 for as long as an unclipping force is not exerted on the security device 30.

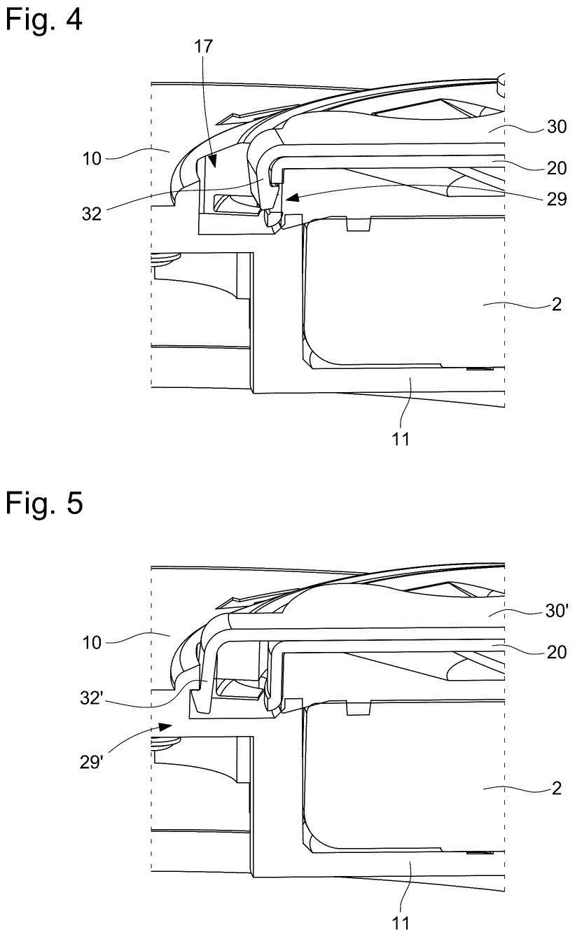

FIG. 4 illustrates a partial cross-sectional view showing the security device 30 clipped onto the cover 20 with one of the attachment clips 32 cooperating with one of the hooking apertures 29 in the cover 20. The shape of the hook on the free end of the attachment clip prevents the security device 30 from being removed until an unclipping force is exerted on the security device 30 to elastically stress the attachment clips 32 and allow the hooks to be released from the hooking apertures 29.

Preferably, the attachment clips 32 are also inserted into notches in the casing 10 so as to prevent any rotation of the security device 30 about the X axis. Thus, when the security device 30 is clipped onto the cover 20, it is no longer possible to rotate the cover 20 and remove it, as the notches 17 prevent the attachment clips 32 from rotating. Thus, the security device 30 has a self-locking function that prevents the cover 20 from rotating.

Preferably, the notches 17 used for mounting the cover 20 and which are free, when the cover 20 is in the closed position, are used to house the attachment clips 32 of the security device 30.

Thus, as can be seen in FIG. 1, when the security device 30 is clipped onto the cover 20, the attachment clips 32 are housed in the notches 17 so that they prevent rotation of the cover 20.

However, if required, it is also possible to make specific notches in the casing 10, i.e. notches different from the notches 17 used for mounting the cover 20, to receive the attachment clips 32 of the security device 30.

The main body 31 of the security device 30 is configured to at least partially cover the cover 20 and its indentation 22, i.e. the recessed surface forming the indentation 22, and preferably a large part of the cover 20 and of the indentation 22.

Thus, the security device 30 renders the indentation 22 unusable for as long as the security device 30 is in place, by superimposing itself on top of the indentation 22.

The main body 31 is dimensioned to sufficiently cover the indentation 22 in the cover 20 so that it is no longer possible to engage a tool in the indentation 22 and thus rotate the cover 20 using the tool in the indentation 22.

The main body 31, for example, has the shape of a disc or pellet, the diameter of which is substantially equivalent to the diameter of the cover 20.

The main body 31 can have a cut-out 36, a break in shape, an opening or a slot configured to allow a tool of small dimensions to reach the indentation 22 of the cover 20 over a limited portion. Thus, it is possible to use a tool of smaller dimensions than that required to rotate the cover 20 via the indentation 22, to make it easier to unclip the security device 30 from the cover 20, particularly when the compartment 11 must be opened in order to replace the cell battery 2. However, this cut-out 36 is not sufficient to rotate the cover using the indentation 22 and a tool adapted to the indentation 22.

To detach the security device 30 during a battery change, the user can easily use a small tool and insert it under the main body 31 at the cut-out 36 in the main body 31, advantageously making use of the removal of material from the indentation 22 in the cover 20. Once the security device 30 has been unclipped and the attachment clips 32 are removed from the hooking apertures 29, the user has access to the indentation 22 in the cover 20, allowing the user to rotate same and access the cell battery 2 housed in the compartment 11.

FIG. 5 illustrates a second example embodiment of a security device according to the invention mounted on a portable electronic item. This second example embodiment is identical to the first example embodiment described above with reference to FIGS. 1 to 4, with the exception of the features which will be described below.

In this second example embodiment illustrated in FIG. 5, the security device 30′ is rigidly connected to the casing 10 by clipping.

To this end, as shown in FIG. 5, the attachment clips 32′ have a hook pointing outwards in a radial direction relative to the central axis X. In this example embodiment, the hooks of the attachment clips 32′ cooperate with hooking apertures 29′ formed in the casing 10 and more particularly on a side face of the notches 17.

Regardless of which example embodiment is applied, the security device 30, 30′ is made of a metal or polymer material.

As shown in FIG. 1, the security device 30, 30′ can also include a security, danger or prevention pictogram 38 visible on the outer face of the security device 30, 30′.

1. A portable electronic item comprising:
a casing having a compartment configured to receive and house at least one removable electrical power source;
a compartment cover including first coupling elements configured to cooperate with second coupling elements provided on the casing so as to rigidly connect the cover to the casing by rotating said cover about a rotational axis formed by a central axis of the cover; said cover having an indentation provided in an outer face, said indentation being configured to receive a tool for rotating the cover; and
a security device rigidly connected by clipping onto said portable electronic item, said security device being configured to at least partially cover the indentation of the cover of the compartment, so as to prevent the introduction of a tool for rotating the cover and removing it from the casing.

2. The portable electronic item according to claim 1, wherein said security device is rigidly connected to the cover by clipping.

3. The portable electronic item according to claim 2, wherein said security device includes:
a main body having a flat surface, and
attachment clips extending from the flat surface of the main body,
the attachment clips cooperating with hooking apertures made in the cover and configured to ensure that the security device is held on the cover by clipping.

4. The portable electronic item according to claim 1, wherein said security device (30′) is rigidly connected to the casing by clipping.

5. The portable electronic item according to claim 4, wherein said security device includes:
a main body having a flat surface, and
attachment clips extending from the flat surface of the main body,
the attachment clips cooperating with hooking apertures made in the casing and configured to ensure that the security device is held on the casing above the cover by clipping.

6. The portable electronic item according to claim 3, wherein said attachment clips project from the flat surface of the main body and extend towards the compartment.

7. The portable electronic item according to claim 6, wherein said casing includes notches formed in the periphery of the cover and in that the attachment clips are housed in the notches so as to prevent the cover from being rotated relative to the casing when the security device is rigidly connected, by clipping, to the portable electronic item.

8. The portable electronic item according to claim 1, wherein said main body has a cut-out allowing a small tool to pass into the indentation to facilitate the unclipping of the security device clipped to the portable electronic item.

9. The portable electronic item according to claim 1, wherein said security device is made of a metal or polymer material.

10. The portable electronic item according to claim 1, wherein said portable electronic item is a timepiece.
